(19) United States
(12) Patent Application Publication
(10) Pub. No.: US 2007/0164371 A1
(43) Pub. Date: Jul. 19, 2007

(54) Reliability degradation compensation using body bias

(76) Inventors: James W. Tschanz, Portland, OR (US); Subhasish Mitra, Palo Alto, CA (US); Vivek K. De, Beaverton, OR (US)

Correspondence Address: Buckley, Maschoff & Talwalkar LLC;Attorneys for INTEL Corporation, Five Elm Street, New Canaan, CT, 06840, US

(21) Appl. No.: 11/321,100

(22) Filed: Dec. 29, 2005

(51) Int. Cl. H01L 29/76

(52) U.S. Cl. 257/391

(57) ABSTRACT

A system may include detection of reliability degradation of a transistor, and change of a body bias applied to the transistor based on the detected reliability degradation.

### BACKGROUND

Metal Oxide Semiconductor (MOS) transistors typically degrade over time. Degradation that affects the reliability of a MOS transistor is referred to as reliability degradation. Reliability degradation may be exacerbated by strong electric fields, high temperatures, and/or age.

Reliability degradation may increase a threshold voltage and therefore reduce a switching speed of a MOS transistor. A p-channel MOS (PMOS) transistor, for example, may experience negative temperature bias instability, a type of reliability degradation in which a magnitude of its threshold voltage increases with age. A MOS transistor may therefore be marketed for operation at a lower frequency than can be achieved by the transistor when new, in order to ensure operation at the lower frequency during the lifetime of the transistor.

### BRIEF DESCRIPTION OF THE DRAWINGS

FIG. 1 is a block diagram of an apparatus and a MOS transistor according to some embodiments.

FIG. 2A is a diagram of a PMOS transistor illustrating a forward body bias according to some embodiments.

FIG. 2B is a diagram of an n-channel MOS (NMOS) transistor illustrating a forward body bias according to some embodiments.

FIG. 3 is a diagram of a process according to some embodiments.

FIG. 4 is a schematic diagram of an apparatus according to some embodiments.

FIG. 5 is a diagram of a process according to some embodiments.

FIG. 6 is a timing diagram of a signal to initiate degradation compensation according to some embodiments.

FIG. 7A is a timing diagram of a body voltage over time according to some embodiments.

FIG. 7B is a timing diagram of a two transistor threshold voltages over time according to some embodiments.

FIG. 7C is a timing diagram of a forward body bias over time according to some embodiments.

FIG. 8 is a block diagram of a system according to some embodiments.

### DETAILED DESCRIPTION

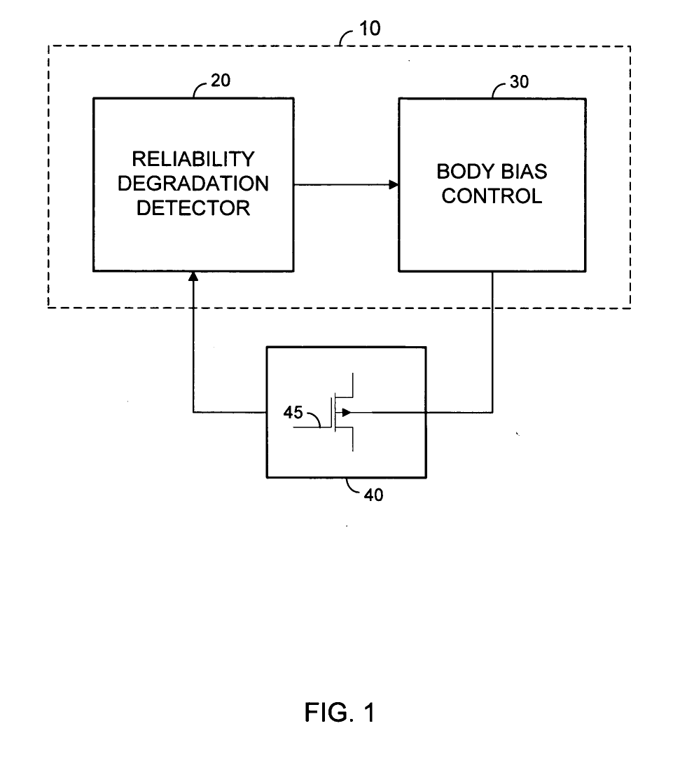

FIG. 1 is a block diagram of an apparatus according to some embodiments. Apparatus 10 may be used to compensate for reliability degradation of MOS devices according to some embodiments. Although the embodiments below are described with respect to MOS transistors, embodiments may include any other suitable type of transistors, including but not limited to field-effect transistors and poly-Si transistors.

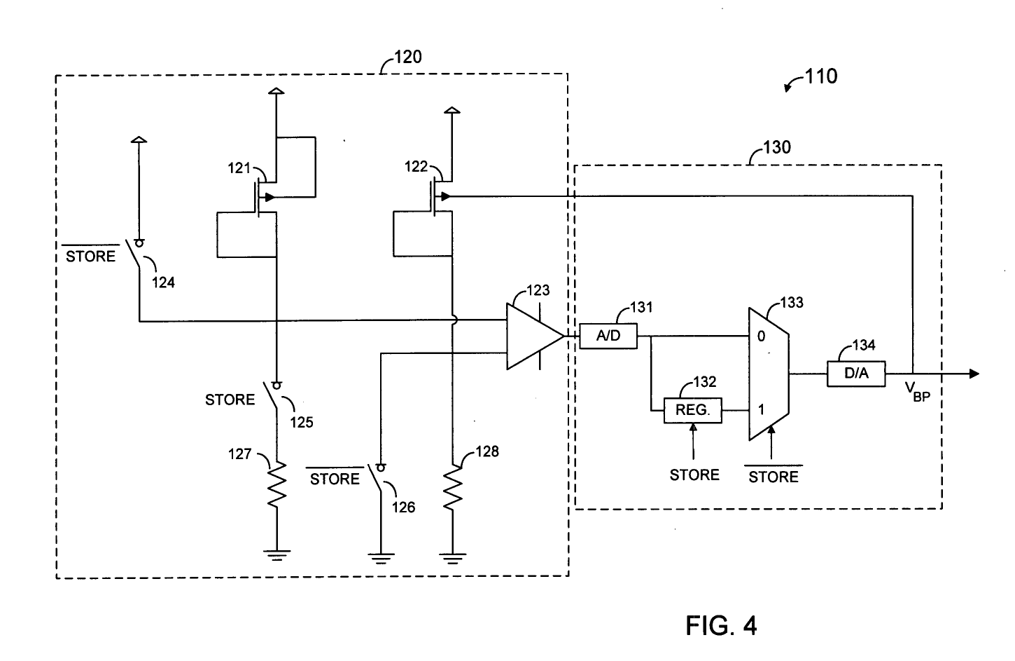

Apparatus 10 includes reliability degradation detector 20 and body bias control 30. Reliability degradation detector 20 is capable of detecting reliability degradation of a MOS transistor. According to some embodiments, reliability degradation detector 20 detects reliability degradation by detecting an increase in the magnitude of the threshold voltage of the MOS transistor. One implementation of reliability degradation detector 20 will be described below with respect to FIG. 4.

Body bias control 30 may change a body bias applied to a MOS transistor. The change may be based on reliability degradation of the MOS transistor that is detected by detector 20. The change may comprise increasing a forward body bias applied to the MOS transistor to decrease the magnitude of the threshold voltage to a desired magnitude.

Apparatus 10 is coupled to integrated circuit 40. Integrated circuit 40 includes one or more integrated electrical devices, including PMOS transistor 45. Integrated circuit 40 may provide any functions that are or become known, and may be fabricated according to any suitable techniques. As described above, reliability degradation detector 20 may detect reliability degradation of PMOS transistor 45 and body bias control 30 may change a body bias applied to PMOS transistor 45 based on the detected reliability degradation.

Reliability degradation detector 20 may detect reliability degradation of PMOS transistor 45 by any currently-or hereafter-known technique. Such techniques include but are not limited to direct measurement of a threshold voltage of PMOS transistor 45, detection of an elapsed period of operation, and measurement of a threshold voltage of another MOS transistor. In addition, one, some, or all elements of apparatus 10 may be integrated into an integrated circuit die and/or package in which integrated circuit 40 and PMOS transistor 45 are integrated.

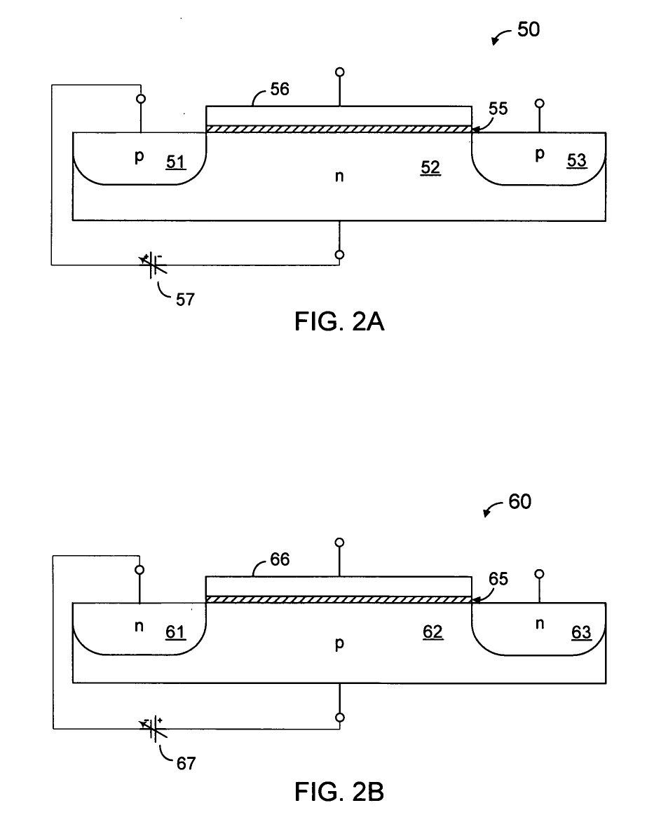

FIGS. 2A and 2B illustrate the above-described forward body biasing of body bias control 30. PMOS transistor 50 of FIG. 2A includes p-type source region 51, n-type body region 52 and p-type drain region 53. Oxide 55 is disposed over body region 52 and conductive element 56 overlays oxide 55. Body bias control 30 of FIG. 1 may comprise forward biasing source 57.

Forward biasing source 57 forward biases the p-n junction of source 51 and body 52 according to some embodiments. More particularly, forward biasing source 57 may increase a forward body bias applied to PMOS transistor 50 based on the detected reliability degradation of PMOS transistor 50. In some embodiments, forward biasing source 57 increases a forward body bias comprises increasing a potential difference between body region 52 and source region 51.

Increasing the forward body bias applied to PMOS transistor 50 may lower a magnitude of a threshold (i.e. “turn on”) voltage of PMOS transistor 50. For example, a threshold voltage V_{TH} of transistor 50 may be −1.1V when a first forward body bias is applied thereto, but −1.0V when the forward body bias is increased. Accordingly, increasing the forward body bias may increase a switching speed of transistor 50 and thereby compensate for any reliability degradation thereof.

FIG. 2B illustrates NMOS transistor 60 according to some embodiments. NMOS transistor 60 includes n-type source region 61, p-type body region 62 and n-type drain region 63. Oxide 65 is disposed over body region 62 and conductive element 66 overlays oxide 65. Forward biasing source 67 may be an element of body bias control 30 of FIG. 1.

Forward biasing source 67 may forward bias the junction of source 61 and body 62. As shown, a polarity of such forward body biasing is opposite to that shown in FIG. 2A. Nevertheless, forward biasing source 67 may increase the forward body bias applied to NMOS transistor 60 by increasing a potential difference between body region 62 and source region 61. The increase may be based on detected reliability degradation of NMOS transistor 60.

A magnitude of a threshold voltage of NMOS transistor 60 may decrease in response to an increased forward body bias. For example, a threshold voltage V_{TH} of transistor 60 may be 1.1V when a first forward body bias is applied thereto, but 1.0V when the forward body bias is increased. Again, the increased forward body bias may increase a switching speed of transistor 60 and thereby compensate for some or all reliability degradation thereof.

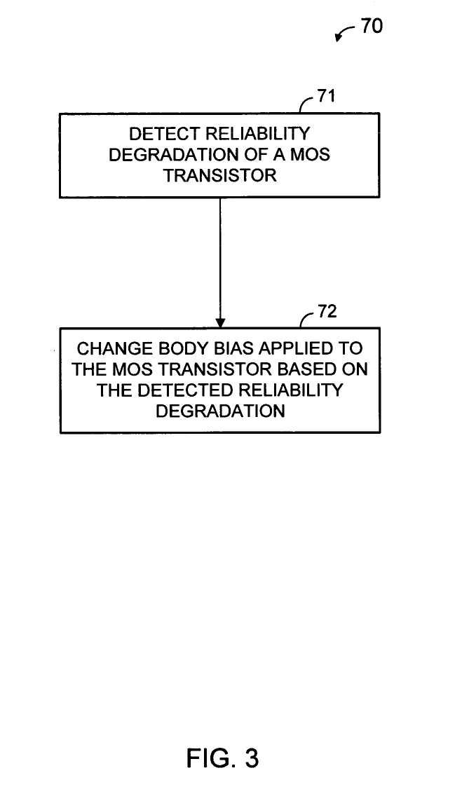

FIG. 3 is a diagram of a general process according to some embodiments. Process 70 may be executed by any combination of hardware and software elements, some of which may be located remote from one another. Some or all of process 70 may be executed manually. According to some embodiments, process 70 is performed by apparatus 10 of FIG. 1.

Initially, at 71, reliability degradation of a MOS transistor is detected. Reliability degradation may be detected at 71 by any techniques that are or become known. In some embodiments, reliability degradation detector 20 measures a threshold voltage of PMOS transistor 45 at 71. Reliability degradation detector 20 then determines that reliability degradation has occurred if a magnitude of the threshold voltage is greater than a predetermined magnitude indicating reliability degradation.

A body bias applied to the transistor is changed at 72. The body bias is changed based on the reliability degradation detected at 71. According to some embodiments of 72, body bias control 30 increases the forward body bias applied to the transistor. The forward body bias may be increased at 72 until a magnitude of the transistor's threshold voltage reaches a desired magnitude. Process 70 may therefore compensate for reduced transistor switching speeds due to reliability degradation.

FIG. 4 is a schematic diagram of apparatus 110 according to some embodiments. Apparatus 110 may operate to detect a reliability degradation of a transistor and to change a body bias of the transistor based on the reliability degradation.

Apparatus 110 includes reliability degradation detector 120 and body bias control 130. Detector 120 includes PMOS transistor 121, PMOS transistor 122, and op-amp 123. Reliability degradation detector 120 may indirectly detect degradation of one or more PMOS transistors (not shown) by comparing a threshold voltage of PMOS transistor 121 with a threshold voltage of PMOS transistor 122 using op-amp 123.

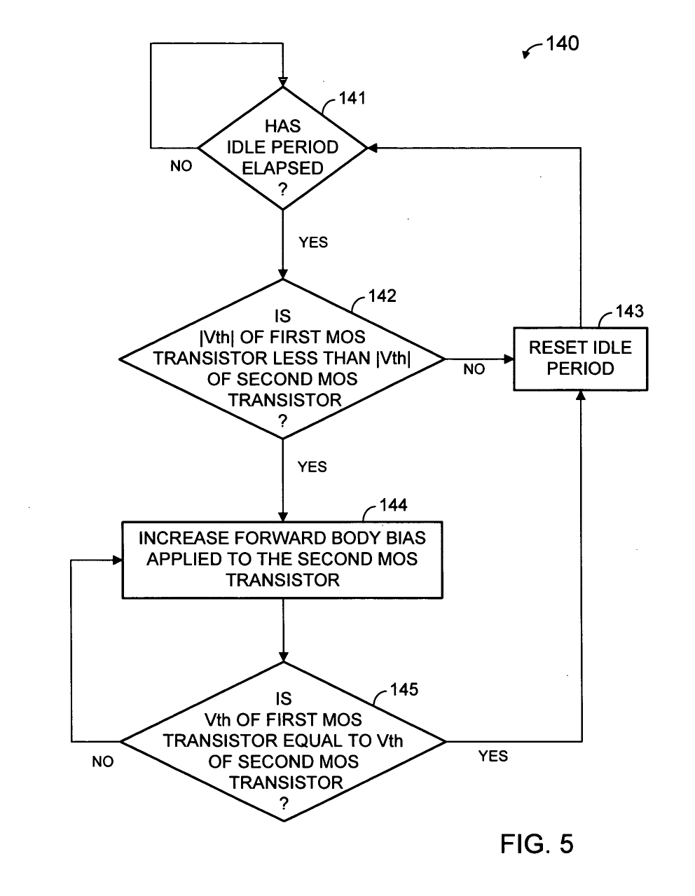

Body bias control 130 includes A/D converter 131, digital register 132, digital demultiplexer 133, and D/A converter 134. Body bias control 130 may receive output from reliability degradation detector 120 and output a body voltage V_{BP} based thereon. The body voltage V_{BP} may be coupled to body regions of the one or more PMOS transistors (not shown) whose degradation is indirectly detected by reliability degradation detector 120. Operation of apparatus 110 according to some embodiments will now be described in conjunction with FIGS. 5 through 7C.

FIG. 5 is a diagram of a process according to some embodiments. Process 140 may also be executed by any combination of hardware and software elements, including but not limited to apparatus 110 of FIG. 4.

Initially, at 140, it is determined whether an idle period has elapsed. The idle period may be a predetermined time period between successive reliability degradation detections. A digital timer and/or counter may track the idle period to determine whether the idle period has elapsed at 141. Flow stalls at 141 until it is determined that the idle period has elapsed.

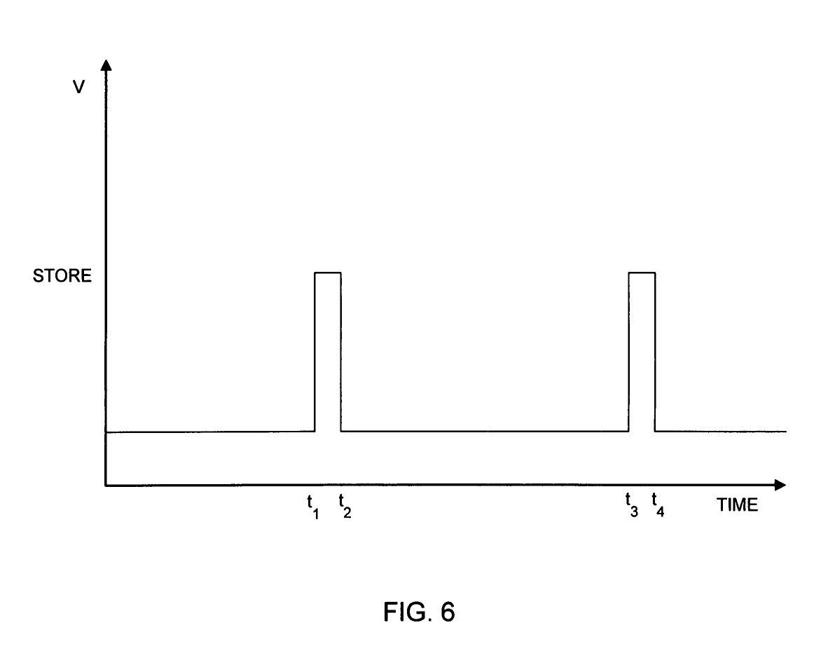

A low STORE signal may be output while flow stalls at 141. The low STORE signal may be output by the aforementioned timer/counter while it determines that the idle period has not elapsed. FIG. 6 comprises a timing diagram of a STORE signal according to some embodiments.

Turning to apparatus 110 of FIG. 4, switches 124 and 126 are closed and switch 125 is open while the STORE signal is low at 141. The STORE signal also selects the lower input of demultiplexer 133 to receive a digital representation of V_{CC} that was pre-stored within register 132. D/A converter 134 converts the representation to V_{CC} and outputs V_{BP}=V_{CC}.

This configuration of switches 124 through 126 causes the gate, source, drain and body of transistor 121 to be held substantially at V_{CC}, the source and body of transistor 122 to be held substantially at V_{CC}, and the gate and drain of transistor 122 to be held substantially at ground. Accordingly, virtually no electric field is present across transistor 121 and a relatively large electric field is present across transistor 122. Such electric field conditions respectively reflect a best and worst case of reliability degradation under operating conditions.

Transistors 121 and 122 are substantially identical prior to operation of apparatus 110. The above-mentioned operation in response to a low STORE signal may cause transistors 121 and 122 to experience different rates of reliability degradation. These different rates may cause a difference in the threshold voltages of transistors 121 and 122. Specifically, a magnitude of a threshold voltage of transistor 122 may increase with respect to a magnitude of a threshold voltage of transistor 121 over time.

Flow proceeds to 142 once the idle period has elapsed. At 142, it is determined whether the magnitude of the threshold voltage of transistor 121 is less than the magnitude of the threshold voltage of transistor 122. As described above, this difference in threshold voltages may indicate reliability degradation in transistor 122. This difference may also indicate reliability degradation in the one or more transistors (not shown) that are also coupled to body voltage V_{BP}.

According to some embodiments, the idle period elapses at time t₁ of FIG. 6 and the STORE signal goes high. Switches 124 and 126 open and switch 125 closes in response. This switch configuration connects transistors 121 and 122 in series with identical resistors 127 and 128. Accordingly, the voltages input to op-amp 123 are dependent solely on the currents through transistors 121 and 122. If the threshold voltages of transistors 121 and 122 are equal, these currents are equal (because transistors 121 and 122 are identical) and the voltages input to op-amp 123 are equal.

Op-amp 123 therefore outputs V_{CC}, which is converted to a digital value by A/D converter 131 and stored in register 132. The high STORE signal also selects the upper input of demultiplexer 133, resulting in transmission of the digital value to D/A converter 134 and output of an analog equivalent as V_{BP}. The store SIGNAL then goes low at t₂ as flow proceeds to 143 to reset the idle period.

Process 140 returns to 141 and continues as described above until the idle period is again determined to have elapsed. For example, the STORE signal again goes high at t₃, causing switches 124 and 126 to open and switch 125 to close in response.

According to the present example, reliability degradation occurring between t₂ and t₃ has caused an increase in the magnitude of the threshold voltage of transistor 122. Op-amp 123 therefore determines at 142 that the magnitude of the threshold voltage of transistor 121 is less than the magnitude of the threshold voltage of transistor 122. Op-amp 123 may base this determination on the receipt at its inputs of two different voltages, the different voltages resulting from the difference in threshold voltage magnitudes.

Op-amp 123 outputs a signal based on the difference, which is stored in register 132 as a digital value and is returned to transistor 122 as body voltage V_{BP}. Op-amp 123 then operates at 144 to increases a forward body bias applied to transistor 122. More particularly, the difference in voltages at the inputs of op-amp 123 causes op-amp 123 to decrease its output voltage, which decreases body voltage V_{BP}, which in turn increases a forward body bias applied to transistor 122.

As described above, increasing a forward body bias applied to transistor 122 decreases a threshold voltage of transistor 122. Therefore, it is determined at 145 whether the threshold voltage of transistor 121 is equal to the threshold voltage of transistor 122. Op-amp 123 may determine that these threshold voltages are not equal at 145 based on different voltages at its inputs. Flow then returns to 144 to decrease body voltage V_{BP} and thereby increase a forward body bias applied to transistor 122 as described above. Accordingly, flow cycles between 144 and 145 until the forward body bias applied to transistor 122 is sufficient to equalize the threshold voltages of transistors 121 and 122.

According to some embodiments, register 132 is updated each time the forward body bias is increased at 144, and the updates cease once the threshold voltages equalize. Therefore, when flow returns to 143 from 145, register 132 stores an indicator of the body voltage V_{BP} that results in the above-mentioned sufficient forward body bias. The indicator may comprise a digital representation of this body voltage V_{BP}.

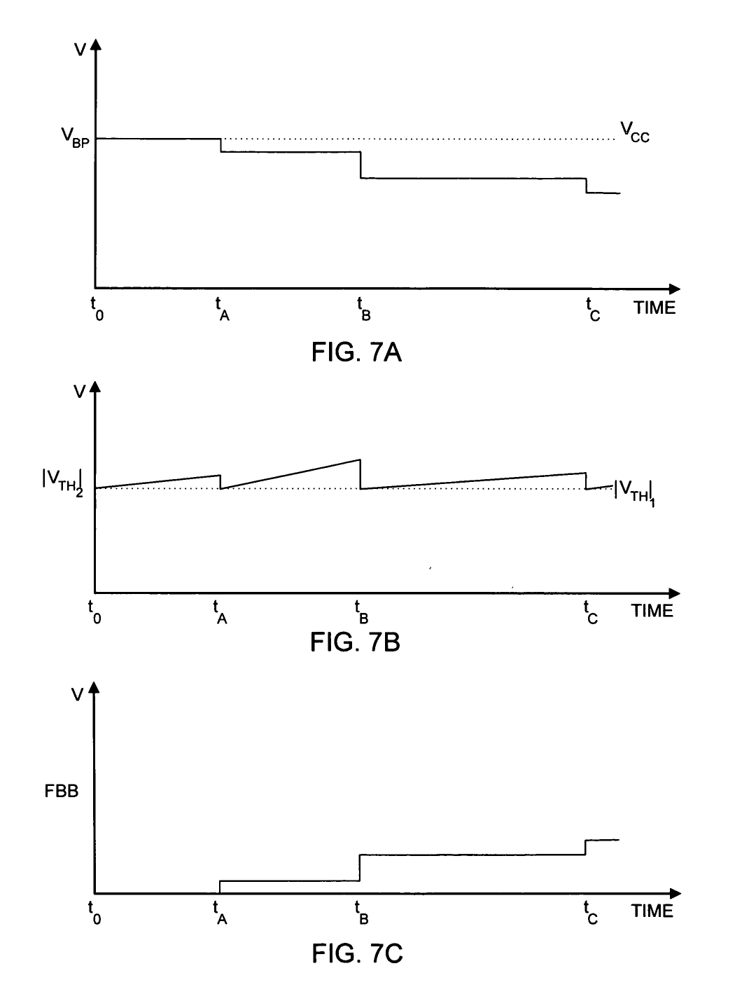

FIGS. 7A through 7C respectively illustrate V_{BP}, a magnitude of the threshold voltage of transistor 122, and a forward body bias applied to transistor 122 according to some embodiments. FIGS. 7A through 7C will be described with respect to process 140 and apparatus 110. For example, times t_{A}, t_{B}, and t_{C} each represent a point in time at which it is determined at 141 that an idle period has elapsed and a STORE signal goes high. Since reliability degradation may occur slowly, and in order to limit the exposure of transistor 121 to an electric field during evaluation of threshold voltages, the idle period may comprise hours or even days.

At time t₀, the magnitude of the threshold voltage of transistor 122 |V_{TH2}| is equal to the magnitude of the threshold voltage of transistor 121 |V_{TH1}|. V_{BP}=V_{CC} and, since the source of transistor 122 is coupled to V_{CC}, no forward body bias is applied to transistor 122. |V_{TH2}| begins to increase after time to due to reliability degradation of transistor 122. The STORE signal goes high at time t_{A}.

In response, op-amp 123 decreases V_{BP} at 144 due to a difference in its input voltages as described above. This decrease increases the forward body bias applied to transistor 122. V_{BP} continues to decrease and the forward body bias continues to increase until op-amp 123 determines that |V_{TH1}|=|V_{TH2}| based on its input voltages. FIG. 7A through FIG. 7C illustrate the decrease of V_{BP}, the increase in the forward body bias, and the equalization of threshold voltages at time t_{A}.

Similar processes occur at time t_{B} and time t_{C}. However, after the elapse of each idle period, V_{BP} decreases from its last value stored in register 132 and the forward body bias increases from its corresponding last value. Such operation results in the pseudo-step functions of FIG. 7A and FIG. 7B.

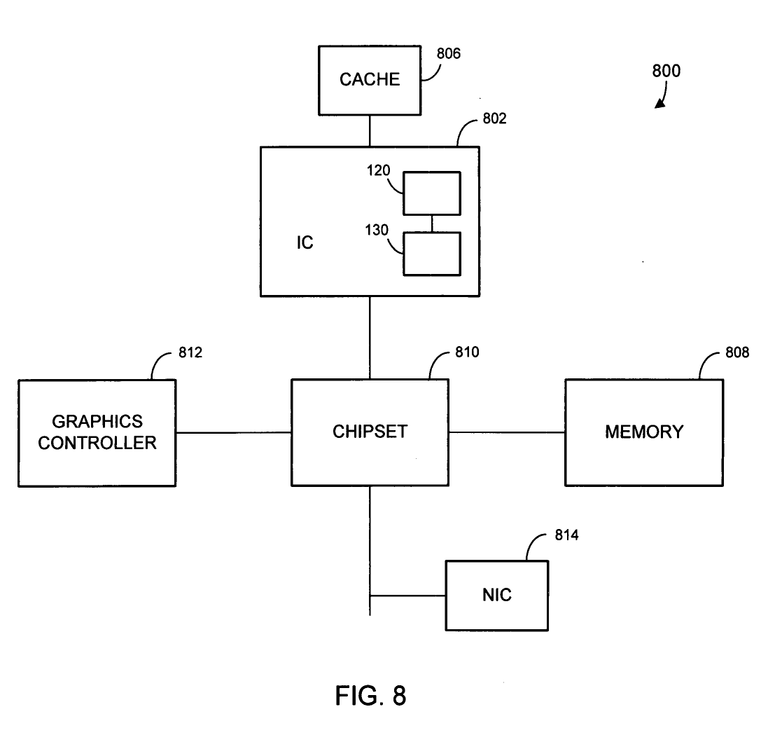

FIG. 8 illustrates a block diagram of system 800 according to some embodiments. System 800 includes integrated circuit 802 comprising reliability degradation detector 120 and body bias control 130. According to some embodiments, detector 120 detects reliability degradation of one or more transistors of integrated circuit 802 and body bias control 130 changes a forward body bias of the one or more transistors based thereon.

Integrated circuit 802 may be a microprocessor or another type of integrated circuit. Integrated circuit 802 communicates with off-die cache 806 according to some embodiments. Integrated circuit 802 may communicate with system memory 808 via a host bus and chipset 810. System memory 808 may comprise any type of memory for storing data, such as a Single Data Rate Random Access Memory, a Double Data Rate Random Access Memory, or a Programmable Read Only Memory. Other off-die functional units, such as graphics controller 812 and Network Interface Controller (NIC) 814, may communicate with integrated circuit 802 via appropriate busses or ports.

The several embodiments described herein are solely for the purpose of illustration. Some embodiments may include any currently or hereafter-known versions of the elements described herein. Therefore, persons in the art will recognize from this description that other embodiments may be practiced with various modifications and alterations.

What is claimed is:

1. A method comprising:
detecting reliability degradation of a transistor; and
changing a body bias applied to the transistor based on the detected reliability degradation.

2. A method according to claim 1, wherein detecting the reliability degradation comprises:
detecting an increase in a magnitude of a threshold voltage of the transistor.

3. A method according to claim 2, wherein changing the body bias comprises:
increasing a forward body bias applied to the transistor to decrease the magnitude of the threshold voltage to a desired threshold voltage magnitude.

4. A method according to claim 1, wherein detecting the reliability degradation comprises:
determining that a first threshold voltage of a first transistor is different from a second threshold voltage of a second transistor.

5. A method according to claim 4,
substantially holding a first gate voltage, a first drain voltage and a first source voltage of the first transistor at a first supply voltage, and
substantially holding a second gate voltage and a second drain voltage of the second transistor at a second voltage and a second source voltage of the second transistor at the first supply voltage.

6. A method according to claim 4, wherein changing the body bias applied to the transistor comprises:
determining a first body bias to change the second threshold voltage of the second transistor to the first threshold voltage of the first transistor; and
applying the first body bias to the transistor.

7. A method according to claim 6, further comprising:
storing an indicator of the first body bias in a memory.

8. An apparatus comprising:
a reliability degradation detector to detect reliability degradation of a transistor; and
a body bias control to change a body bias applied to the transistor based on the detected reliability degradation.

9. An apparatus according to claim 8, wherein the reliability degradation detector is to detect an increase in a magnitude of a threshold voltage of the transistor.

10. An apparatus according to claim 9, wherein the body bias control is to increase a forward body bias applied to the transistor to change the magnitude of threshold voltage to a desired threshold voltage magnitude.

11. An apparatus according to claim 8, wherein the reliability degradation detector comprises:
a first transistor having a first threshold voltage; and
a second transistor having a second threshold voltage,
wherein the reliability degradation detector is to determine that the first threshold voltage is different than the second threshold voltage.

12. An apparatus according to claim 11,
wherein the reliability degradation detector is to substantially hold a first gate voltage, a first drain voltage and a first source voltage of the first transistor at a first supply voltage, and
wherein the reliability degradation detector is to substantially hold a second gate voltage and a second drain voltage of the second transistor at a second voltage, and to hold a second source voltage of the second transistor at the first supply voltage.

13. An apparatus according to claim 11, wherein the body bias control is to determine a first body bias to change the second threshold voltage of the second transistor to the first threshold voltage of the first transistor, and to apply the first body bias to the transistor.

14. An apparatus according to claim 13, wherein the body bias control comprises a memory to store an indicator of the first body bias.

15. An apparatus according to claim 11, the reliability degradation detector further comprising:
an operational amplifier, a first input of the operational amplifier coupled to a source of the first transistor, a second input of the operational amplifier coupled to a source of the second transistor, and an output of the operational amplifier coupled to a body of the second transistor,
wherein the first transistor is diode-connected and the second transistor is diode-connected.

16. A system comprising:
a microprocessor comprising:
a transistor;
a reliability degradation detector to detect reliability degradation of the transistor; and
a body bias control to change a body bias applied to the transistor based on the detected reliability degradation; and
a double data rate memory coupled to the microprocessor.

17. A system according to claim 16, wherein the reliability degradation detector is to detect an increase in a magnitude of a threshold voltage of the transistor, and
wherein the body bias control is to increase a forward body bias applied to the transistor to change the magnitude of threshold voltage to a desired threshold voltage magnitude.

18. A system according to claim 16, wherein the reliability degradation detector comprises:
a first transistor having a first threshold voltage; and
a second transistor having a second threshold voltage,
wherein the reliability degradation detector is to determine that the first threshold voltage is different than the second threshold voltage.

19. A system according to claim 18, wherein the body bias control is to determine a first body bias to change the second threshold voltage of the second transistor to the first threshold voltage of the first transistor, and to apply the first body bias to the transistor.
